(19) United States
(12) Patent Application Publication
(10) Pub. No.: US 2026/0086448 A1
(43) Pub. Date: Mar. 26, 2026

(54) PHOTOLITHOGRAPHIC MASK PATTERN GENERATION WITH OPTICAL PROXIMITY CORRECTION RULES DETERMINED USING SCATTERED DATA INTERPOLATION

(71) Applicant: TEXAS INSTRUMENTS INCORPORATED, Dallas, TX (US)

(72) Inventors: Jakin Delony, Addison, TX (US); Gerard Luk-Pat, Dallas, TX (US); Steve Prins, Fairview, TX (US); Scott Jessen, Allen, TX (US)

(21) Appl. No.: 19/287,423

(22) Filed: Jul. 31, 2025

Related U.S. Application Data
(60) Provisional application No. 63/698,263, filed on Sep. 24, 2024.
(60) Provisional application No. 63/762,316, filed on Feb. 24, 2025.

(51) Int. Cl. G03F 1/36; G03F 7/00

(52) U.S. Cl. CPC G03F 1/36; G03F 7/0005; G03F 7/70441

(57) ABSTRACT

Mask patterns and mask devices for photolithography used in semiconductor and other device fabrication are described. For example, a method of fabricating a semiconductor device includes generating, utilizing an optical proximity correction model, a first mask pattern for formation of geometric features using a first mask pattern comprising a first set of mask features. The method also includes determining, based at least in part on a rules-based optical proximity correction data structure, adjustments to the first mask pattern to generate a second mask pattern, wherein the rules-based optical proximity correction data structure characterizes predicted deviations which would result from formation of at least one of the geometric features utilizing the first mask pattern, the predicted deviations being determined by performing scattered data interpolation on measured error data. The method further includes forming, utilizing a photolithographic mask device having the second mask pattern, the geometric features in a material layer.

### CROSS-REFERENCE TO RELATED APPLICATIONS

This application claims the benefit of and priority to U.S. Provisional Patent Application No. 63/698,263 (Texas Instruments Docket No. T105535US01), filed on Sep. 24, 2024, and to U.S. Provisional Patent Application No. 63/762,316 (Texas Instruments Docket No. T105535US02), filed on Feb. 24, 2025, which applications are hereby incorporated herein by reference in their entirety.

### TECHNICAL FIELD

The present disclosure relates to the field of photolithography, and more particularly to photolithographic masks and devices fabricated using such photolithographic masks.

### BACKGROUND

Photolithography is a frequently used process in semiconductor and other device fabrications. While some photolithography techniques are maskless, where light is applied directly to a photosensitive material of a photoresist layer formed on a semiconductor or other layer of the device being fabricated, other photolithography techniques utilize a mask device (referred to, e.g., as a mask or reticle). In the latter case, light is shone onto a surface of the mask device positioned between the light source and the semiconductor device being fabricated. Based on a mask pattern formed on a surface of the mask device, light passes through the mask device to the photoresist layer in certain areas while being blocked in other areas.

A mask device can be a clear field mask or a dark field mask. In a clear field mask, the patterned features on a surface of the mask device block light while the other surface areas pass light. Conversely, in a dark field mask, the patterned features pass light, while the other surface areas block light. Still further, the underlying photoresist layer formed on the device being fabricated can be positive or negative. In a positive photoresist, portions of the photosensitive material are removed when exposed to light and developed. Conversely, in a negative photoresist, portions of the photosensitive material are removed when developed unless exposed to light.

A profile is thereby formed in the photoresist layer based on the mask pattern and then transferred to the underlying layer of the device being fabricated to form one or more structures therein.

### SUMMARY

The present disclosure describes mask patterns and mask devices for photolithography used in semiconductor and other device fabrication. This summary is not an extensive overview of the disclosure. Rather, a purpose of the summary is to present some examples of the present disclosure in a simplified form as a prelude to a more detailed description that is presented later.

In some examples, a method includes determining measured error data characterizing one or more deviations in formation of a first subset of a plurality of geometric features in a material layer using a first photolithographic mask device, the first photolithographic mask device having a first mask pattern comprising one or more mask features designed utilizing an optical proximity correction model. The method also includes determining, by performing scattered data interpolation based at least in part on the measured error in the formation of the first subset of the plurality of geometric features, interpolated error data characterizing one or more predicted deviations which would result from formation of a second subset of the plurality of geometric features using the first photolithographic mask device having the first mask pattern. The method further includes generating a rules-based optical proximity correction data structure characterizing the measured error data and the interpolated error data, and generating a second mask pattern for a second photolithographic mask device utilizing the optical proximity correction model and the generated rules-based optical proximity correction data structure.

In some other examples, an apparatus includes at least one processor and at least one memory storing instructions that, when executed by the at least one processor, cause the apparatus to determine measured error data characterizing one or more deviations in formation of a first subset of a plurality of geometric features in a material layer using a first photolithographic mask device, the first photolithographic mask device having a first mask pattern comprising one or more mask features designed utilizing an optical proximity correction model. The instructions, when executed by the at least one processor, also cause the apparatus to determine, by performing scattered data interpolation based at least in part on the measured error in the formation of the first subset of the plurality of geometric features, interpolated error data characterizing one or more predicted deviations which would result from formation of a second subset of the plurality of geometric features using the first photolithographic mask device having the first mask pattern. The instructions, when executed by the at least one processor, further cause the apparatus to generate a rules-based optical proximity correction data structure characterizing the measured error data and the interpolated error data, and generate a second mask pattern for a second photolithographic mask device utilizing the optical proximity correction model and the generated rules-based optical proximity correction data structure.

In some additional examples, a method of fabricating a semiconductor device includes generating, utilizing an optical proximity correction model, a first mask pattern for formation of one or more geometric features using a first mask pattern comprising a first set of one or more mask features. The method also includes determining, based at least in part on a rules-based optical proximity correction data structure, one or more adjustments to the first mask pattern to generate a second mask pattern, wherein the rules-based optical proximity correction data structure characterizes one or more predicted deviations which would result from formation of at least one of the one or more geometric features utilizing the first mask pattern, the one or more predicted deviations being determined by performing scattered data interpolation on measured error data. The method further includes forming, utilizing a photolithographic mask device having the second mask pattern, the one or more geometric features in a material layer over a semiconductor substrate.

### BRIEF DESCRIPTION OF THE DRAWINGS

FIG. 1 is a block diagram of a mask device fabrication process with which one or more examples of the present disclosure may be implemented;

FIG. 2 is a block diagram of a process for patterning a photoresist layer utilizing a mask device in accordance with examples of the present disclosure;

FIG. 3 is a block diagram of a process for adjusting a mask pattern utilizing an optical proximity correction model in accordance with examples of the present disclosure;

FIG. 4 shows patterning of material layers with and without an optical proximity correction model adjusted mask pattern in accordance with examples of the present disclosure;

FIGS. 5A-5C show examples of calibration data for an empirical optical proximity correction model in accordance with an example of the present disclosure;

FIG. 6 shows a plot of optical proximity correction model residuals in accordance with an example of the present disclosure;

FIG. 7 shows another plot of optical proximity correction model residuals in accordance with an example of the present disclosure;

FIG. 8 shows another plot of optical proximity correction model residuals in accordance with an example of the present disclosure;

FIG. 9 shows a process flow for generation of optical proximity correction rules for an optical proximity correction model utilizing scattered data interpolation in accordance with an example of the present disclosure;

FIG. 10A shows a rules-based table for an optical proximity correction model with sparse data in accordance with an example of the present disclosure;

FIG. 10B shows a two-dimensional plot of the sparse data in the rules-based table of FIG. 10A in accordance with an example of the present disclosure;

FIG. 10C shows a convex hull for the two-dimensional plot of FIG. 10B in accordance with an example of the present disclosure;

FIG. 10D shows triangulation of the convex hull for the two-dimensional plot of FIG. 10C in accordance with an example of the present disclosure;

FIG. 10E shows interpolated data for the two-dimensional plot of FIG. 10B in accordance with an example of the present disclosure;

FIG. 11 shows plots of quantified model error and rules-based optical proximity correction applied to compensate for the quantified model error for one-dimensional line thru pitch features in accordance with an example of the present disclosure;

FIG. 12 shows plots of quantified model error and rules-based optical proximity correction applied to compensate for the quantified model error for one-dimensional space thru pitch features in accordance with an example of the present disclosure;

FIG. 13 shows plots of quantified model error and rules-based optical proximity correction applied to compensate for the quantified model error for two-dimensional pillar and slot features in accordance with an example of the present disclosure;

FIG. 14 is a flow diagram of a methodology for photolithographic mask pattern generation with optical proximity correction rules determined using scattered data interpolation in accordance with examples of the present disclosure;

FIG. 15 is a block diagram of a computer system with which one or more examples of the present disclosure can be implemented; and

FIG. 16 is a block diagram of a distributed communications/computing network with which one or more examples of the present disclosure can be implemented.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean+/−10-20 percent of the stated value.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, photolithographic mask devices are used to form one or more structures in a semiconductor device or other types of devices. While photolithographic techniques have been proposed to enable fabrication of structures with certain shapes, they have largely focused on two-dimensional (2D) shaping, e.g., mainly linear-based shapes defined in x and y dimensions on a plane where the structures have substantially perpendicular sidewalls in a z dimension orthogonal to the plane. However, one specific form of photolithography, referred to as grayscale photolithography, has been proposed to facilitate three-dimensional (3D) structure shaping, e.g., structures defined in x and y dimensions on a plane with non-perpendicular (e.g., sloped, tapered, contoured) sidewall profiles.

More particularly, grayscale mask-based lithography uses a mask device (e.g., sometimes referred to as a grayscale mask or grayscale reticle) to spatially modulate or modify the light intensity or dosage applied to a photoresist layer formed on an underlying layer of the device being fabricated. By way of example, the light applied to the grayscale mask device typically is ultra-violet (UV) light. Modulation of the light is enabled by a patterned opaque layer disposed on a light-passing substrate. The patterned opaque layer includes areas of opaque material (opaque areas of the patterned opaque layer) and areas without opaque material (open areas of the patterned opaque layer where a surface of the light-passing substrate is exposed). For example, the opaque areas can be composed of a metal material such as, but not limited to, chrome, chromium, and/or a metal oxide. The light-passing substrate can be composed of a light-passing material such as, but not limited to, quartz, fused silica, and/or glass. Thus, in one example, a grayscale mask device can be fabricated where chrome serves as the opaque material and glass serves as the light-passing material. Such a mask device is sometimes referred to as a chrome-on-glass (COG) mask. In general, such a mask can also be referred to as a binary mask given its functionality to block light in certain areas and pass light in other areas.

During the grayscale photolithographic process, the applied light is blocked or obstructed by opaque areas of the patterned opaque layer while passing through the open areas and then through the substrate. More particularly, grayscale mask devices rely on the concept of diffraction where light bends or spreads around the edges of the opaque areas while passing through the open areas of the patterned opaque layer.

Accordingly, the term “opaque,” as illustratively used herein, refers to a characteristic of a material to block applied light by reflection, absorption, and/or some other light-blocking functionality. The term “light-passing,” as illustratively used herein, refers to a characteristic of a material to enable all or most of the applied light to pass (e.g., transparent material), or some portion of the applied light to pass (e.g., translucent or semitransparent material).

In a clear field mask, the pattern features formed in the patterned opaque layer on a surface of the light-passing substrate are composed of opaque material and thus block light, while clear or open areas (lack of opaque material) expose the surface of the light-passing substrate and thus pass light. In contrast, in a dark field mask, the pattern features on the surface are clear or open areas (pass light) while the other areas on the surface are opaque material and thus block light. Depending on the structures being fabricated in the underlying device, either type of mask device (clear field or dark field) can be used with a positive photoresist material or a negative photoresist material.

The modulated light passing through the mask device, e.g., measured as an intensity-pass percentage, correspondingly modulates or modifies the amount of photosensitive material that is removed (positive photoresist) or remains (negative photoresist) in the photoresist layer to form a profile in the photoresist layer. Thus, in a positive photoresist example, the more light that passes through the mask device (e.g., higher intensity-pass percentage) onto the photoresist layer, the more photosensitive material of the photoresist layer is removed during development (e.g., decreasing the thickness of the photoresist layer from its original thickness). Thus, by modulating the applied light to change the exposure dose or intensity locally in the photoresist layer, profiles can be selectively formed in the photoresist layer, e.g., non-perpendicular photoresist sidewall profiles. The profiles can then be transferred to the underlying layer of the semiconductor device to fabricate various structures of the semiconductor device.

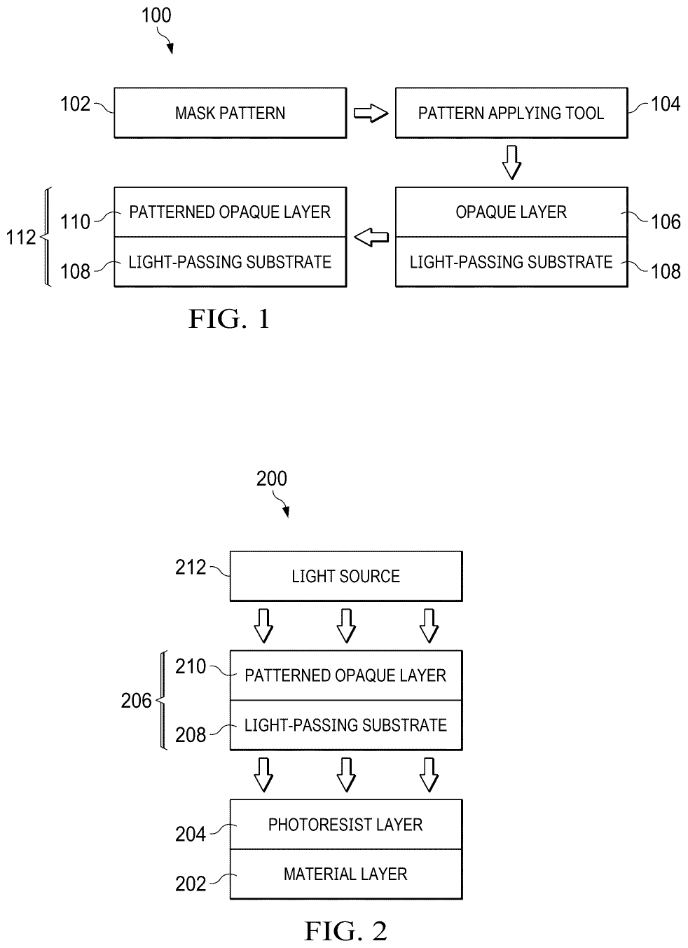

Referring now to FIG. 1, a mask device fabrication process 100 is generally shown. Initially, a mask pattern 102 is generated. In some examples, mask pattern 102 is generated using a computer-based software package such as a computer-aided design (CAD) system. The CAD system enables a designer, on a computer system with a graphical user interface, to create an image of a specific geometry of features on a layout grid that will result in a specific profile being formed in a photoresist layer. The specific profile in the photoresist layer then dictates the resulting shape (e.g., contour) of one or more corresponding structures in the underlying layer of the semiconductor device. One example of a layout grid on which a designer can lay out mask pattern features via the CAD system is a coordinate grid of equally-sized square cells. However, as will be further described, alternative layout grids can be used.

Once generated, mask pattern 102 is input to a pattern applying tool 104. For example, mask pattern 102 generated by the designer via the CAD system can be saved as a software data file that is readable by pattern applying tool 104. Pattern applying tool 104 is configured to read the mask pattern file and transfer the mask pattern 102 onto an opaque layer 106 disposed on a surface of a light-passing substrate 108 resulting in a patterned opaque layer 110, as shown in FIG. 1.

In some examples, pattern applying tool 104 is a laser-based pattern writing system. Preparation of the opaque layer 106 prior to the laser-based pattern writing process may be dependent on the particular system being used. However, in some examples, opaque layer 106 will have its own photoresist layer disposed thereon (not expressly shown) such that mask pattern 102 is applied to the photoresist layer. After development, mask pattern 102 is transferred to opaque layer 106 resulting in patterned opaque layer 110.

Accordingly, as shown in FIG. 1, a mask device 112 is fabricated including light-passing substrate 108 with the patterned opaque layer 110 disposed thereon. Patterned opaque layer 110, as mentioned above, includes opaque areas that, during semiconductor device fabrication, reflect, absorb, or otherwise block the applied light while allowing light to pass through open areas (e.g., where no opaque material is disposed) and thus through the light-passing substrate 108.

The complexity of structures formed in a semiconductor device using a mask device (e.g., mask device 112) is directly related to the mask pattern (e.g., mask pattern 102) formed on the mask device. Accordingly, the mask pattern dictates the positioning of the features in the patterned opaque layer (e.g., patterned opaque layer 110) of the mask device and thus the profile formed in a photoresist layer. However, the fabrication of the mask device with its mask pattern design can present technical challenges to designers, as well as to the pattern applying tools that are utilized, depending on the desired profiles and structures. This is particularly the case when generating mask patterns that are intended to result in more complex structures in the semiconductor device, e.g., 3D structures based on grayscale photolithography and the like.

Referring now to FIG. 2, a semiconductor device fabrication process 200 is generally shown. The semiconductor device fabrication process 200 involves modification of a material layer 202, such as by patterning or implant. A photoresist layer 204 is formed over the material layer 202. A mask device 206 is used to create a pattern in the photoresist layer 204, with that pattern then being transferred to the underlying material layer 202. The mask device 206 includes a light-passing substrate 208 having a patterned opaque layer 210 disposed on a surface thereof. A light source 212 is applied to the mask device 206, which results in the mask pattern of the mask device 206 (e.g., defined in the patterned opaque layer 210) being transferred to the photoresist layer 204. The mask pattern can then be transferred to the material layer 202 (e.g., by etching portions of the material layer 202 which are exposed by the patterned photoresist layer 204).

Optical Proximity Correction (OPC) is a resolution enhancement technique (RET) which may be used in semiconductor device fabrication processes to refine pattern accuracy of mask devices (e.g., mask device 112, mask device 206). OPC, for example, can refine pattern accuracy on a material layer over a substrate by compensating for optical distortions and process variations (e.g., introduced by diffraction, interference effects and process variability in photolithography). These distortions cause deviations between the intended circuit design and the printed features on a wafer or material layer, impacting both pattern fidelity and device performance. An OPC model may be used to refine mask patterns to compensate or otherwise account for such optical distortions and process variations (e.g., by systematically modifying photomask geometries to correct for these distortions, ensuring high-volume manufacturability for advanced technology nodes).

An OPC model provides a simulation of the photolithography process to predict how a given optics source and mask shape will pattern on a wafer or material layer. OPC models may rely upon a series of modeling terms and features. The model terms describe various components of the photolithography process, including but not limited to: optics; acid/base diffusion; resist loading; pattern density; etc. The OPC model enables pre-manipulation of design (e.g., target) polygons or other geometric features on a mask, to result in a printed pattern over a wafer or material layer that is as close to the design intent as possible. OPC may be used for achieving various goals, including but not limited to: preventing catastrophic failures (e.g., opens and shorts); minimizing variation in line-widths (e.g., particularly at gates); preventing “line-end pullback” or shortening of lines; and controlling rounding of corners.

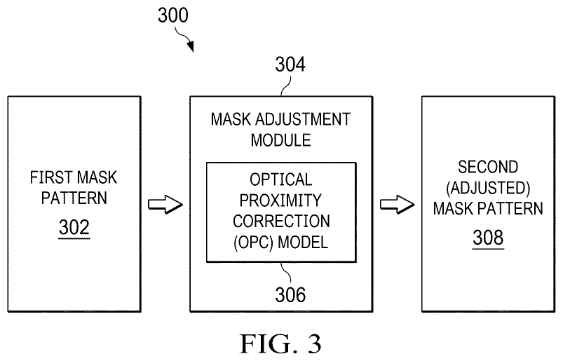

Referring now to FIG. 3, a mask pattern adjustment process 300 is illustrated, where a mask adjustment module 304 implementing an OPC model 306 is configured to adjust a first mask pattern 302 to generate a second (adjusted) mask pattern 308.

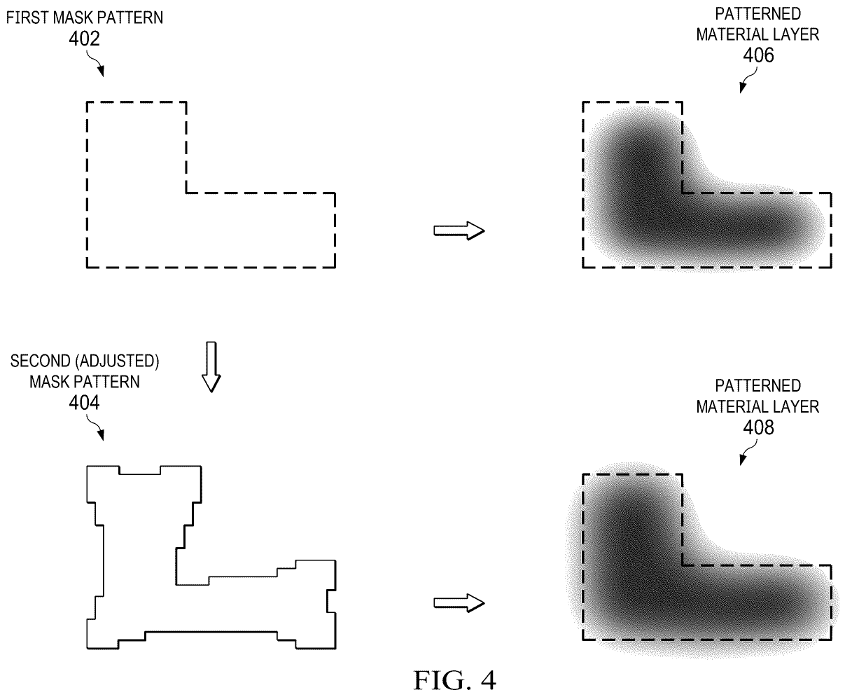

Referring now to FIG. 4, processes for patterning a material layer utilizing a first mask pattern 402 and a second (adjusted) mask pattern 404 are illustrated. Lithography has limited spatial bandwidth, such that the shapes drawn by designers, e.g., in the first mask pattern 402, may not lead to the same shapes in a material layer, e.g., the patterned material layer 406 which is patterned with a mask device using the first mask pattern 402. In this example, optical proximity effects can lead to undesired outcomes in patterned features of the first mask pattern 402, such as line-end shortening and corner rounding. An OPC model tunes the designed shapes to generate an adjusted mask pattern, e.g., the second mask pattern 404, that produces printed features that more accurately reflect the design intent. When patterning with a mask device utilizing the second (adjusted) mask pattern 404, the resulting patterned material layer 408 has shapes which are closer to the designed shapes.

In some examples, OPC employs a blend of rules-based and model-based treatments to correct the intended circuit design. Rules-based OPC (RB-OPC) uses a table or series of tables (e.g., one or more rules-based tables (RBTs)) that prescribe discrete treatments for a feature as a function of its surrounding environment. RB-OPC may be utilized for applications such as etch bias compensation, silicon process bias definition, and OPC model correction. A drawback to defining an RBT is that the empirical measurements used to populate the RBT are typically sparse in terms of feature size and pitch, requiring the OPC engineer to fully populate the RBT via other means. The empirical measurements may include sparse Critical Dimension Scanning Electron Microscope (CD-SEM) and/or transmission electron microscopy (TEM) data, which requires extensive manual analysis and engineering judgment for generating intermediate rules.

Mask device fabrication processes are described herein which utilize an OPC model and one or more rules-based OPC data structures (e.g., RBTs for RB-OPC) to provide improved OPC performance. Measured error data is determined, where the measured error data characterizes one or more deviations in formation of a first subset of a plurality of geometric features in a material layer using a first photolithographic mask device having a first mask pattern including one or more mask features designed utilizing the OPC model. Scattered data interpolation is performed, based at least in part on the measured error in the formation of the first subset of the plurality of geometric features, to determine interpolated error data characterizing one or more predicted deviations which would result from formation of a second subset of the plurality of geometric features using the first photolithographic mask device having the first mask pattern. One or more rules-based OPC data structures (e.g., RBTs for RB-OPC) are generated, where the rules-based OPC data structures characterize both the measured error data and the interpolated error data. A second (e.g., adjusted) mask pattern for a second photolithographic device is generated utilizing the OPC model and the generated rules-based OPC data structures. Advantageously, rather than interpolating RBTs manually, scattered data interpolation techniques according to the disclosure are leveraged to automatically populate the RBTs at the desired level of granularity. Scattered data interpolation uses unevenly distributed sparse sample points to characterize the behavior of an entire region. While examples of the disclosure may be expected to provide improvements such as described, no particular result is a requirement of the present invention unless explicitly recited in a particular claim.

As noted above, OPC is a type of RET in semiconductor manufacturing. Global size adjustments (GSA) is another type of RET used in semiconductor manufacturing, in which all mask features are uniformly resized to compensate for systematic process variations. Selective size adjustments (SSA) is still another type of RET, in which corrections are applied based on feature dimension. With continued scaling, GSA and SSA approaches have been rendered obsolete as feature scaling has continued to progress beyond the wavelength of the illumination source. RB-OPC, also referred to as complex SSA, provides more localized and context-aware corrections. RB-OPC relies on pre-defined correction rules, stored in RBTs or other OPC data structures. The RBTs prescribe feature-specific modifications based on a feature's surrounding environment.

RB-OPC is able to efficiently correct optical proximity effects without the computational burden of rigorous simulation. However, the robustness of RB-OPC solutions is heavily dependent on the proper classification of feature types (e.g., one-dimensional (1D) versus two-dimensional (2D)), as well as the ability to parameterize these features in a way that allows for comprehensive rule definitions. As feature scaling has continued to progress, the increase in feature complexity requires more comprehensive RBTs, leading to progressively longer run times for execution.

Model-based OPC (MB-OPC) employs physics-driven, iterative simulations to refine mask features, capturing multidimensional and context-dependent lithographic effects. Significant advances in OPC modeling, including inverse lithography technology and deep learning-based optimization, have further enhanced model-based techniques.

In some examples, MB-OPC is used as a primary OPC mechanism, with RB-OPC being used as a complementary technique. RB-OPC, for example, provides significant advantages in areas such as etch bias correction, silicon process bias definition and OPC model correction. For etch bias correction, etch bias effects are generally non-linear through pitch. Context-dependent etch bias may be corrected via RB-OPC, as plasma etch effects are highly complex and difficult to simulate accurately. Unlike optical proximity effects, which can be modeled through physics-based simulations, plasma etching introduces nonlinear feature dependencies that vary significantly based on process conditions. Though improvements in etch modeling have been realized, especially with the incorporation of machine learning techniques, empirical rule-based corrections derived from etch process characterization are still needed. For silicon process bias definition, for complex pattern levels such as trenches, silicon process bias is applied as a function of feature size and pitch to ensure that the resist targets for each feature size are lithographically feasible. For OPC model correction, if the through-pitch targeting response of post-OPC features do not meet process specifications, an RBT can be applied to compensate for known model error.

A significant challenge in RB-OPC implementation is defining a comprehensive RBT when the empirical data (e.g., CD-SEM/TEM measurements) which define these rules are sparse in terms of sampling across the allowable feature size and pitch. Conventional approaches rely on manual interpolation or “stair-step” binning, which introduces inconsistencies and inaccuracies in OPC corrections as they rely upon engineering judgment and fundamental process knowledge. Incorporating scattered data interpolation introduces a scalable and systematic method for populating RBTs in a way that improves both RB-OPC accuracy and efficiency.

In some examples, scattered data interpolation is used to address the challenge of input data sparsity to automate the population of RBTs or RB-OPC. Delaunay triangulation may be used as the scattered data interpolation algorithm in some examples. Compared to manual stair-step interpolation or look-up table-based approaches, Delaunay triangulation offers a flexible, spatially aware interpolation framework that can be generalized across OPC design surfaces. Advantages of Delaunay triangulation for RB-OPC rule generation include: robust handling of sparse data, through ensuring correction rules are interpolated consistently across the design space; geometric fidelity, through preserving spatial relationships between neighboring data points, reducing artifacts introduced by over-smoothing or global interpolation; and computation efficiency, providing a balance of accuracy and feasibility, making it suitable for large-scale, computationally intensive OPC applications.

OPC models are calibrated using a collection of CD-SEM/TEM data measuring test patterns that comprise the design surface of the given pattern level. The objective is to regress the OPC model such that the simulated contour CDs align with the measured CD-SEM/TEM data. Despite efforts to improve OPC model accuracy, calibrated models will always contain residual errors. In some examples, a target root-mean squared error (RMSE) metric is for the residual errors to be less than a designated threshold (e.g., 2 nm).

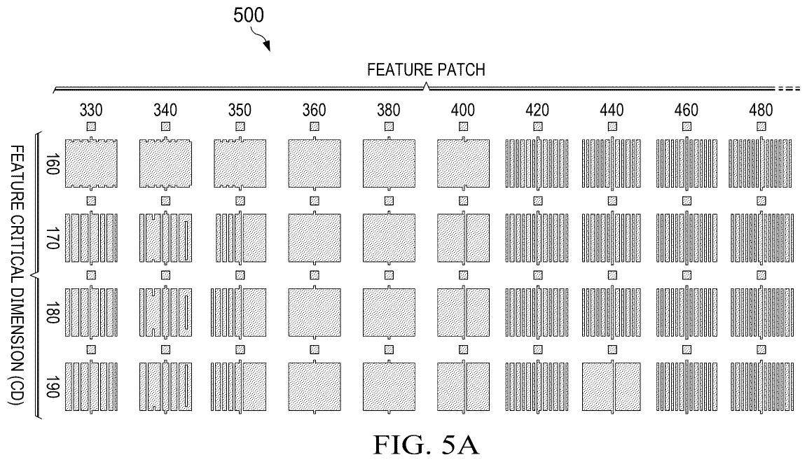

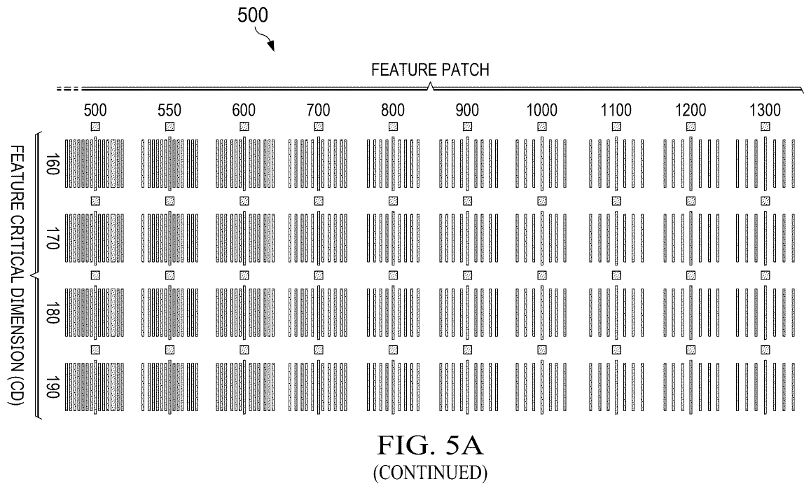

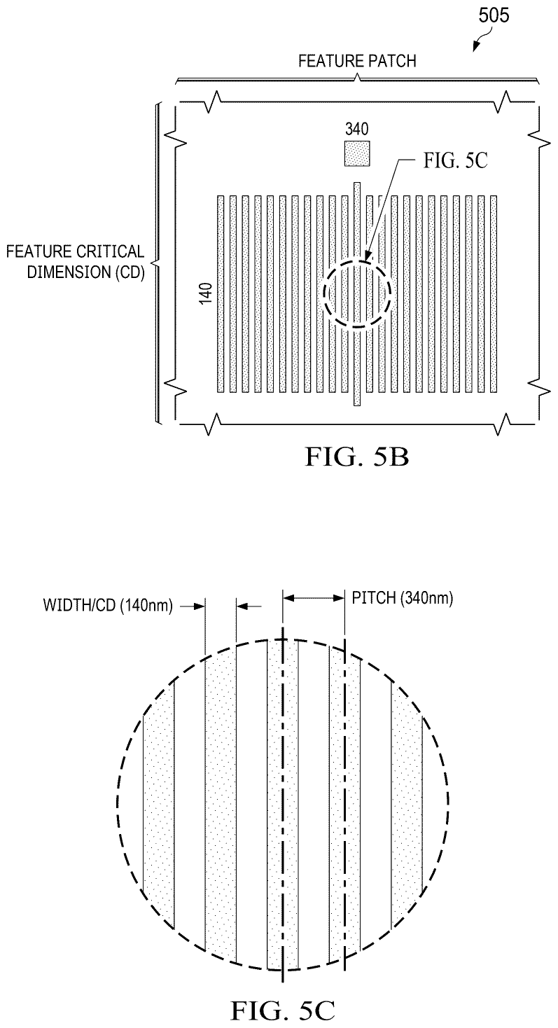

The baseline OPC solution for a material layer of interest uses an empirically calibrated OPC model. While some examples are described with respect to the material layer of interest being an implant layer, the material layer is not limited to being an implant layer. In other examples, the material layer includes a semiconductor layer, a metal layer, an oxide layer, an organic layer, etc. Empirical wafer measurements constituting this model are collected using an OPC test reticle containing non-OPC treated features that cover the design space for this implant layer, following the scheme depicted in FIGS. 5A-5C.

Referring now to FIG. 5A, calibration data 500 for an empirical OPC model including CD-SEM measurement data is illustrated. The calibration data 500 includes various examples of feature pitch and feature CD. A calibration data file may include or specify feature coordinates, mask CD and measured CD (e.g., resist CD, etch CD, etc.). The resist CD and etch CD may be measured via CD-SEM metrology. The calibration data may include line thru pitch (LTP) and space thru pitch (STP) data. Referring now to FIGS. 5B and 5C, a specific element 505 of the calibration data 500 is shown in more detail. Here, the element 505 is for the feature pitch of 340 nm and feature CD (e.g., width) of 140 nm.

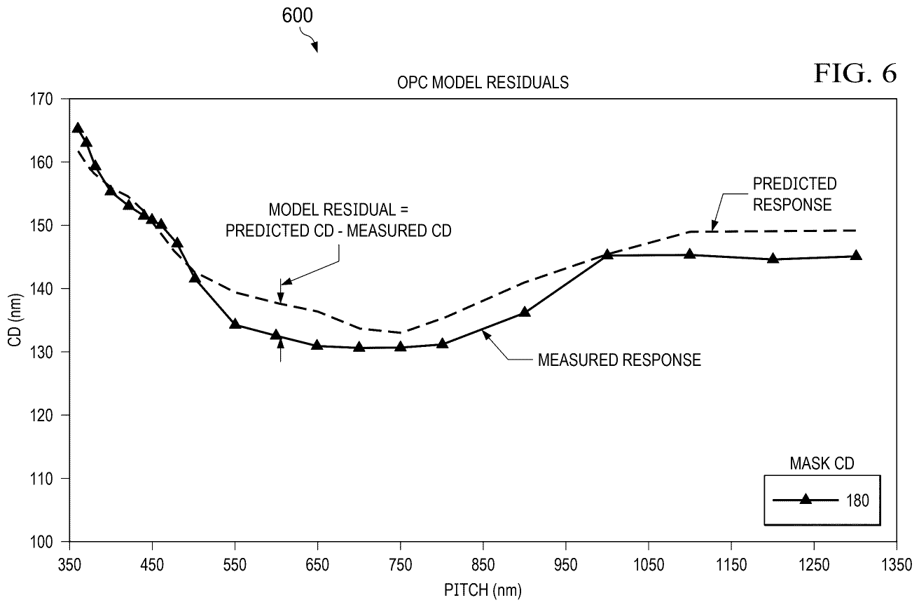

Referring now to FIG. 6, a plot 600 of OPC model residuals is shown. The plot 600 shows the CD as a function of pitch, for a specific example of a mask CD of 180 nm. The model residual is determined by computing a difference between the predicted CD (shown as a solid line in the plot 600) and the measured response (shown as the line with triangular data points in the plot 600).

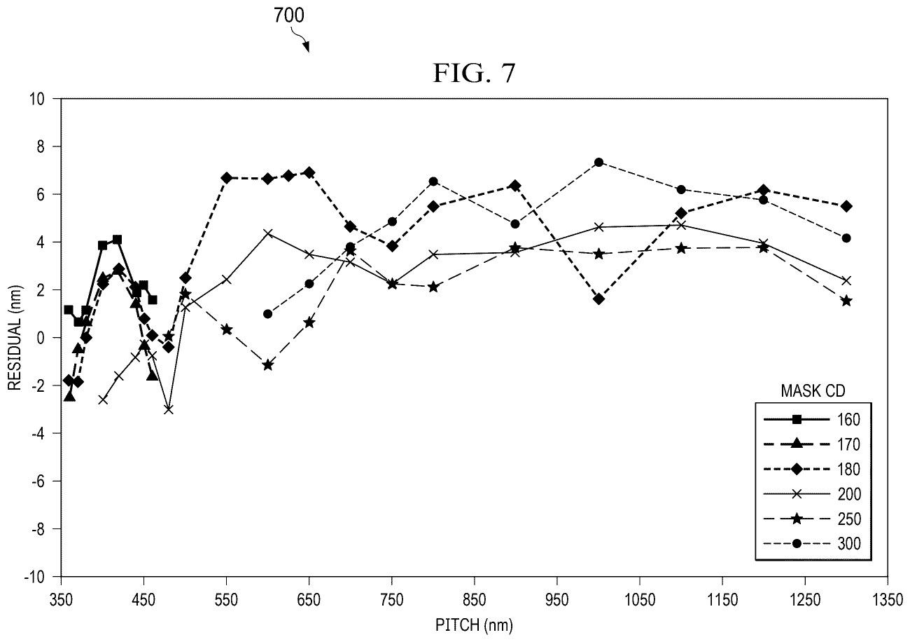

Referring now to FIG. 7, a plot 700 of OPC LTP model residuals is shown for various mask CDs (e.g., 160 nm, 170 nm, 180 nm, 200 nm, 250 nm and 300 nm). The plot 700 shows the residual as a function of pitch.

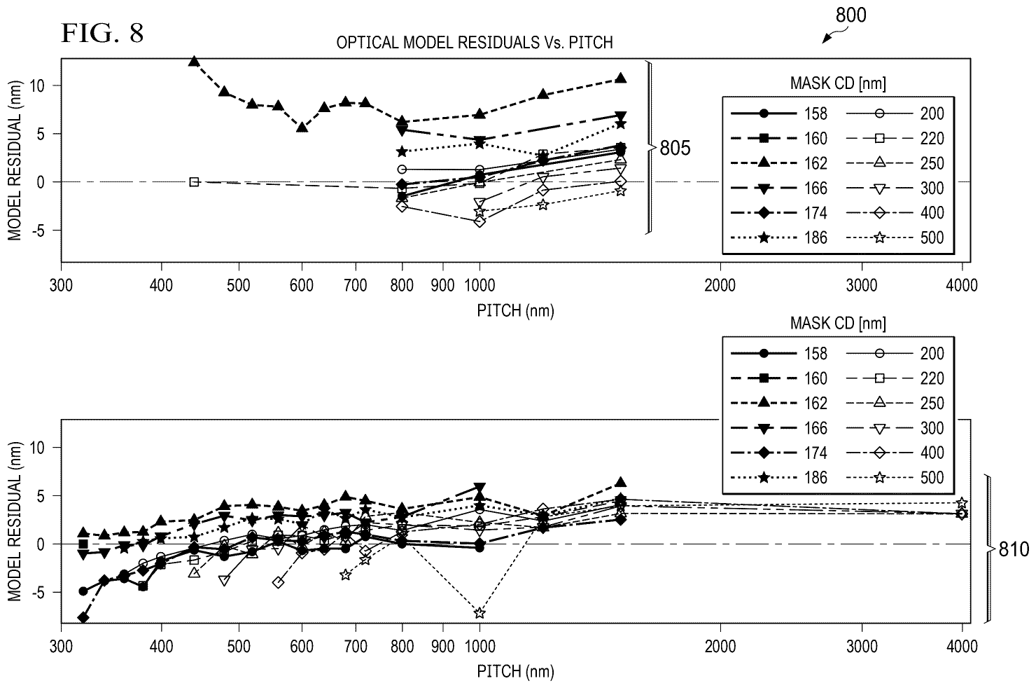

Referring now to FIG. 8, a plot 800 of the optical OPC model error (e.g., model residuals) as a function of pitch is shown. The optical OPC model has a fixed model threshold that ensures symmetry about the process anchor. The model verification residuals for drawn lines (the top region 805 of the plot 800) and spaces (the bottom region 810 of the plot 800) indicate that RBT corrections could improve feature targeting, particularly for narrow features (e.g., 162 nm lines). As shown in the plot 800, for a 28 nm implant process, validation data reveals the OPC optical model error to be on the order of 10 nm for 162 nm drawn features. Different methods of correction may be utilized, including: calibrating the empirical OPC model, which is resource- and time-intensive (e.g., taking two or more weeks in some cases); and utilizing RB-OPC where one or more RBTs are used to correct the output of an OPC model (e.g., the empirical OPC model or an optical OPC model), which is more easily accessible and less time-intensive (e.g., taking 1-2 hours in some cases).

The OPC model residuals quantify the differences in model contour predictions from the empirical data set used to calibrate the OPC model. The OPC model residuals allow a model engineer to visualize model “goodness” as a function of feature geometry. Extensive metrology and characterization is costly, both from a materials and engineering time perspective.

In some examples, an assortment of test patterns are selected as features for model calibration (e.g., 198 one-dimensional and 3 two-dimensional test patterns). The calibration features are selected to represent the full design space in terms of feature size, pitch and tone (e.g., lines and spaces). For testing, a pilot (e.g., nonintegrated) wafer is exposed by a parametric annular illumination source, and the calibration features are measured using CD-SEM. Annular illumination sources are one subset of parametrically defined source shapes. Parametric sources are used for exposing all pattern levels of legacy technology nodes and non-critical pattern levels of more advanced technology nodes (e.g., 28 nm implant pattern levels). Annular sources are characterized by the radius of the inner ring (σᵢₙ) and the radius of the outer ring (σₒᵤₜ). CD measurements are averaged across multiple fields (e.g., 5 fields) on the wafer to account for cross-wafer uniformity and to mitigate against measurement outliers.

After collecting the model calibration dataset, a model template is configured with components including: an illumination source, a resist stack, a reticle tone and blank type, a process anchor, and calibration data. The configured model template is imported into a model calibration engine provided by electronic design automation (EDA) software. Using a covariance matrix adaptation evolution strategy (CMA-ES), the model is calibrated by optimizing both the optical and resist parameters which comprise the convolution kernels within the model. The optimization is characterized by a user-defined cost function, which contains elements that quantify both the accuracy of the model and its stability throughout the design domain. Components of the cost function include model calibration RMSE and error range, as well as penalties for model threshold and contrast values which deviate from known acceptable ranges.

The optical OPC model in some examples is configured in a manner similar to that of the empirical OPC model, with one important distinction. Instead of using a full through-pitch empirical dataset for calibration, the optical OPC model is configured with a single data point: the process anchor for the implant layer of interest. Using a desired anchor of 160 nm mask CD on a 320 nm pitch targeting 160 nm in resist, the model threshold is effectively fixed so that the model contour CD matches the desired resist target. Because the model threshold degree of freedom is effectively removed, the optical and resist parameters no longer need to be tuned and are instead fixed at their “ideal” values. Only two parameters are tuned manually prior to exporting the optical OPC model: optical focal plane delta and optical sigma. The optical focal plane delta defines the iso-focal plane within the photoresist. This parameter must be tuned in optical models to ensure that the model is centered at the best focus for the given illumination source. The optical sigma defines the diffusion length of the diffused aerial image. In some cases, the optical sigma for the optical OPC model is fixed at 20 nm.

When constructing the optical OPC model, the anchor structure is the only feature of importance. Within the OPC model engine, the model threshold is fixed such that the contour CD is perfectly symmetric about the desired target size. As noted above, the anchor feature in some examples is a 160 nm mask feature at 320 nm pitch, with a 160 nm resist target. The optical OPC model is verified by generating model contours for every feature of the empirical OPC model calibration dataset. Next, the model residuals (e.g., model error on a per-feature basis) are calculated. These model residuals are shown as a function of mask size and pitch in the plots 600, 700 and 800 of FIGS. 6-8. The quantified optical OPC model residuals serve as sparse input data which is subject to scattered data interpolation as discussed below.

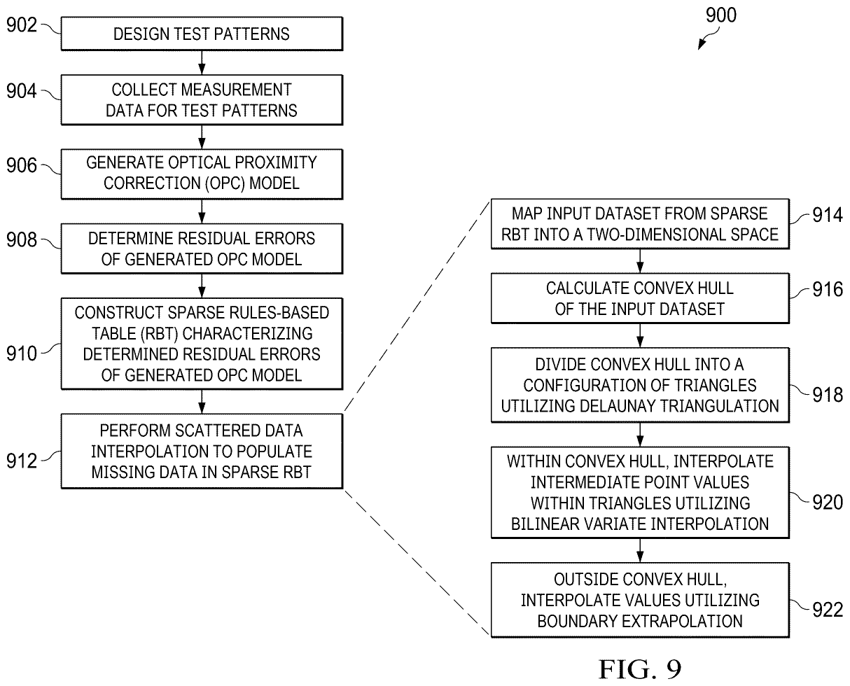

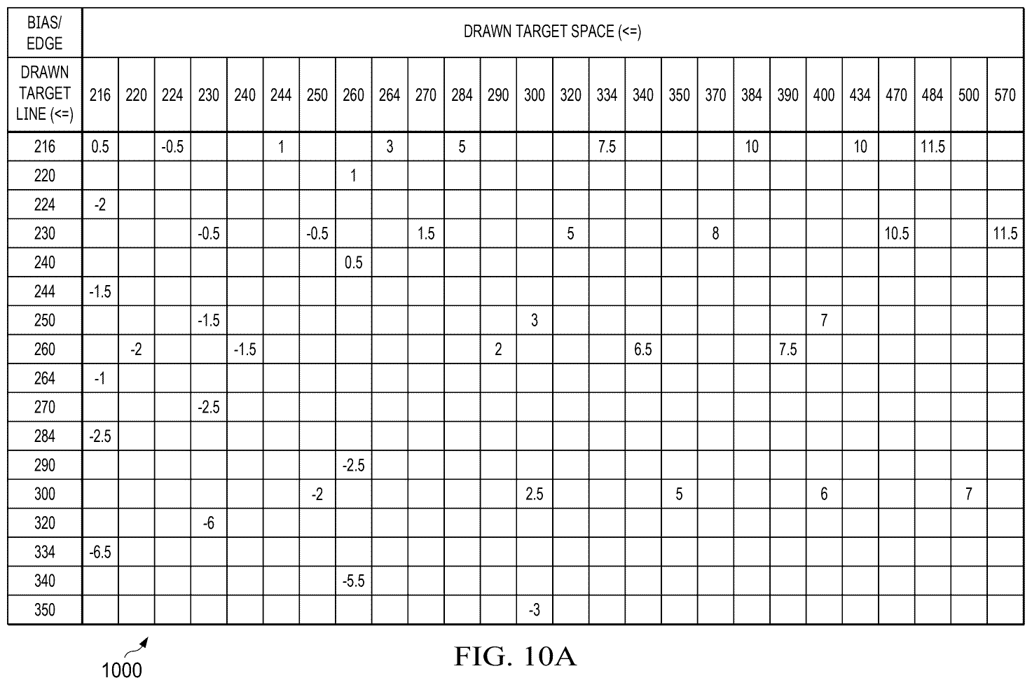

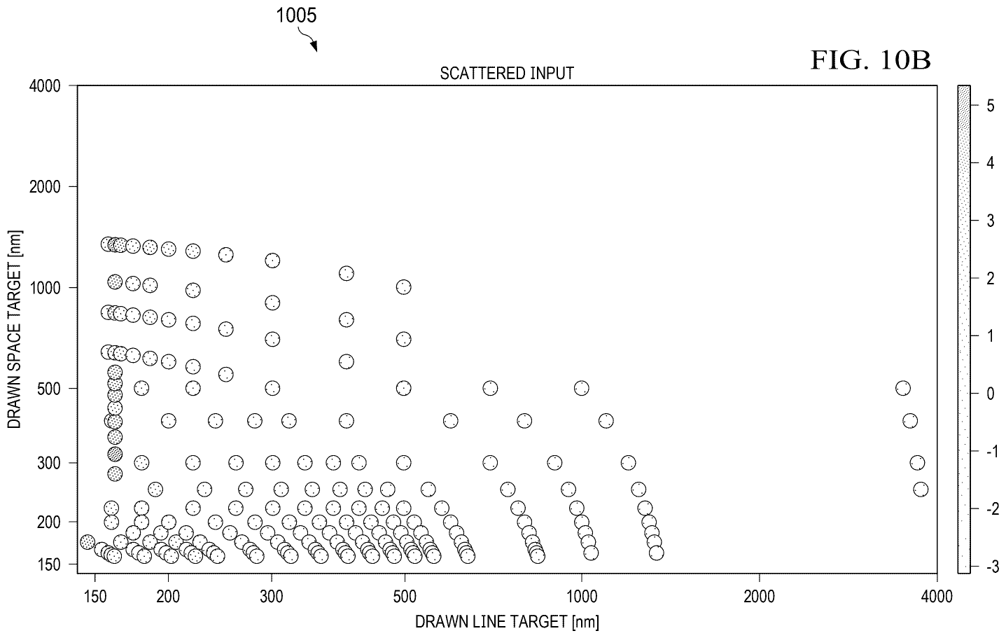

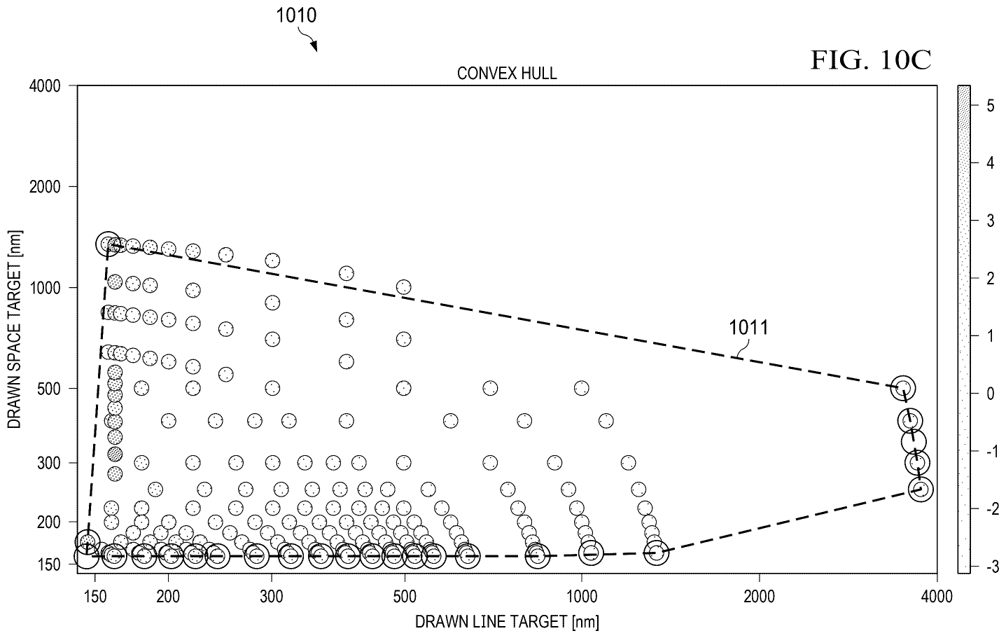

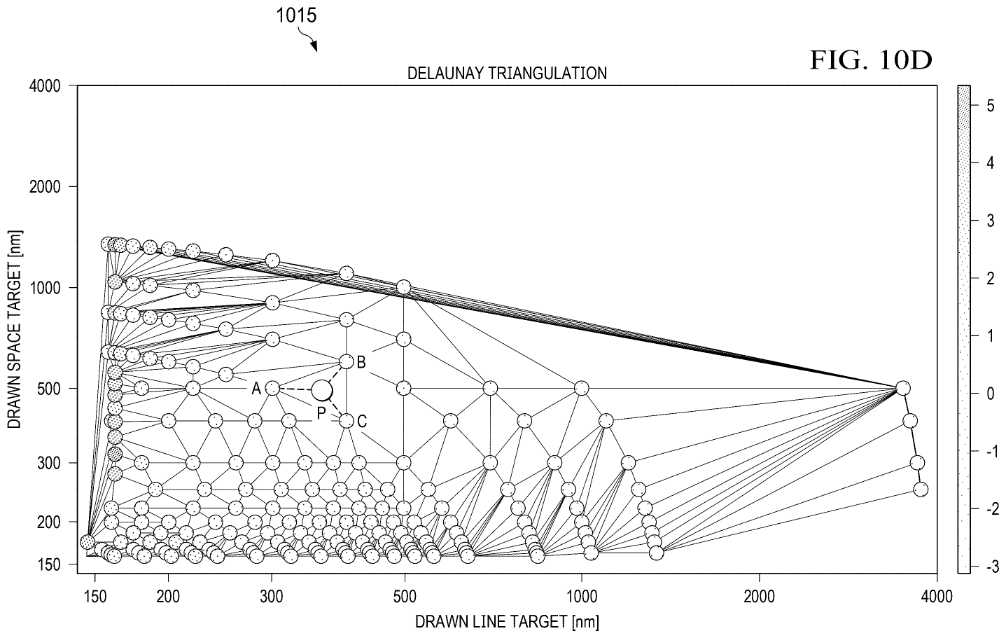

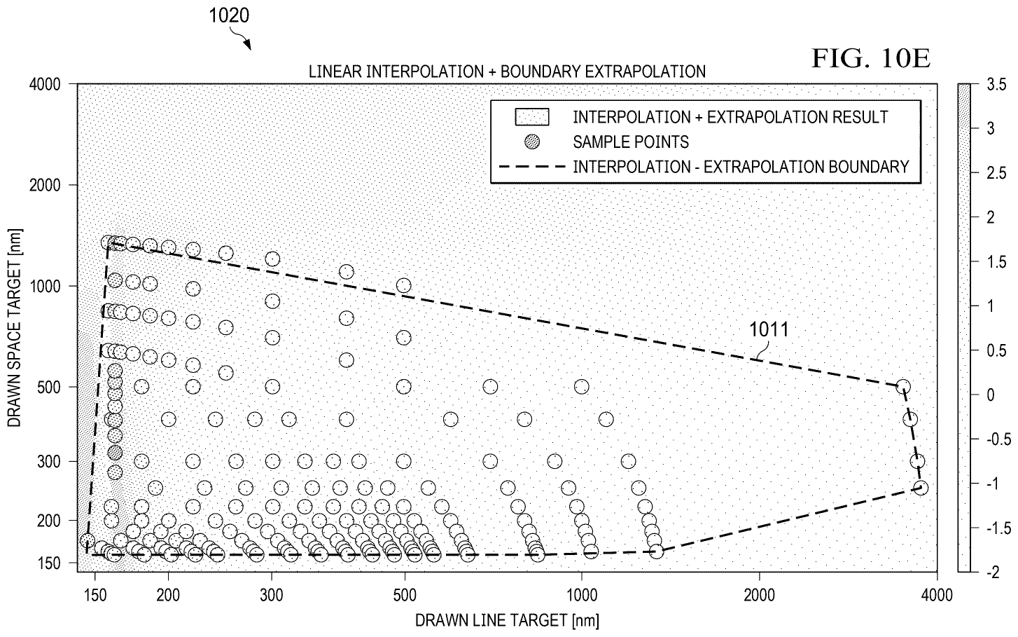

Referring now to FIG. 9, a process flow 900 for building an OPC model and one or more rules-based OPC data structures (e.g., RBTs) utilizing scattered data interpolation is shown. The process flow 900 begins with designing test patterns in block 902. The test patterns are designed for a material layer that is to be patterned. In block 904, measurement data for the test patterns is collected. In block 906, an OPC model is generated utilizing the collected measurement data for the test patterns. Residual errors for the generated OPC model are determined in block 908, followed by constructing a sparse RBT characterizing the determined residual errors of the generated OPC model in block 910. FIG. 10A shows a table 1000 illustrating an example of a portion of a sparse RBT. The table 1000 provides a sparse input dataset of measured error values or model residuals characterizing the required total feature mask bias adjustment for drawn target line and drawn target space values. In block 912, scattered data interpolation is performed to populate missing data in the sparse RBT constructed in block 910. The scattered data interpolation in block 912 may include various sub-step processing blocks 914 through 922.

In block 914, the input dataset is mapped from the sparse RBT into a two-dimensional space. FIG. 10B shows a plot 1005 of the scattered input (e.g., the table 1000) mapped to a two-dimensional space where the drawn space target is plotted as a function of the drawn line target. In block 916, a convex hull of the input dataset is calculated. FIG. 10C shows a plot 1010 where the convex hull 1011 for the input dataset is overlayed over the plot 1005. In block 918, the convex hull is divided into a configuration of triangles utilizing Delaunay triangulation. FIG. 10D shows a plot 1015 where the convex hull 1011 is divided into a configuration of triangles. In block 920, within the convex hull, intermediate point values are interpolated within each of the triangles utilizing a linear interpolation algorithm (e.g., bilinear variate interpolation). In block 922, outside the convex hull, values are interpolated utilizing boundary extrapolation. FIG. 10E shows a plot 1020 illustrating results of performing linear interpolation as well as boundary extrapolation.

Scattered data interpolation, in some examples, includes multiple steps: (1) sparse, empirical RBT definition; (2) execution of Delaunay triangulation; and (3) data processing and export to an OPC engine.

For the sparse, empirical RBT definition, the optical OPC model residuals serve as the sparse input data points used for scattered data interpolation. This is done by classifying each feature in the verification dataset by feature width, space, tone and dimensionality (e.g., 1D versus 2D features). Ordinarily, each feature's mask error enhancement factor (MEEF) is characterized according to:

$$MEEF = \frac{{measCD}_{y} - {measCD}_{x}}{{maskCD}_{y} - {maskCD}_{x}}$$

where y is one feature size larger than the feature of interest, and x is one feature size smaller than the feature of interest. In some examples, for simplicity, every feature is assumed to have an ideal MEEF=1, meaning that 1 nm of mask perturbation results in 1 nm of measured perturbation on wafer. This is a reasonable assumption for 248 nm lithography processes such as implants. For more challenging 193 nm or extreme ultraviolet lithography (EUV) processes, this assumption does not hold.

The required total feature mask bias adjustment is calculated according to the following equations for line features (bias_{L}) and space features (bias_{S}):

$${bias}_{L} = \frac{model error}{MEEF}$$

$${bias}_{S} = \frac{model error}{MEEF}$$

where model error is the model residual for that feature, and the MEEF is assumed to be equal to one. Next, the total feature bias is divided by two to obtain the bias needed per feature edge, since the RB-OPC engine defines bias corrections on a per-edge basis. The total feature bias (e.g., the total mask bias adjustment needed) values may be rounded to be compliant with the reticle grid size or database unit (DBU). In some examples, non-critical levels receive OPC treatment with 0.5 nm resolution.

All 1D feature types are re-combined and sorted by ascending feature width, and this table is output (e.g., in a comma-separated value (.csv) format). A sample of this data is shown in Table 1 below:

TABLE 1
Sample Empirical RBT (units in nm)

| Width | Space | Bias |
|---|---|---|
| 146 | 174 | 3.8300 |
| 154 | 166 | 0.5250 |
| 158 | 162 | −0.5125 |
| 158 | 642 | −0.7250 |

Scattered data interpolation utilizing Delaunay triangulation is then performed on the RBT. The sparse RBT may be imported into MATLAB or other suitable software. An example of scattered input data, defined in terms of line width, space width and bias value, is shown in the table 1000 of FIG. 10A, which is plotted in two-dimensional space as shown in the plot 1005 of FIG. 10B. The bias values in the table 1000 are derived from the optical OPC model residuals, in addition to the feature geometry. Because the data is irregularly spaced on both x and y axes, this dataset is suitable for scattered data interpolation.

Scattered data interpolation is performed on the input dataset, using a linear method for interpolation and a boundary method for extrapolation. Where MATLAB is used, the built-in scatteredInterpolant function may be utilized for performing scattered data interpolation. Delaunay triangulation is executed on the scattered input points to interpolate between them. In some examples, the granularity of the output grid is perturbed, as binning widths of 5 nm, 10 nm, 50 nm and 100 nm are tested. Delaunay triangulation executes the following sequence of steps: (1) computing the convex hull, (2) triangulating data that falls within the convex hull, and (3) interpolating points that belong to the triangles of the triangulated data falling within the convex hull.

The convex hull of the scattered input data is computed in order to determine the interpolation/extrapolation boundary, shown in the plot 1010 of FIG. 10C as the convex hull 1011. The convex hull 1011 can be thought of as a rubber band stretched around the boundary of the data points and then released, containing all points while minimizing the perimeter of the shape. It should be noted that in the plot 1010 of FIG. 10C, the convex hull 1011 appears to exclude outer points, but this is just an artifact of the logarithmic axis scaling used.

Data that falls within the convex hull 1011 of the dataset is triangulated by connecting all the neighboring points in the Voronoi diagram of the input point set. This is illustrated by the plot 1015 of FIG. 10D. Triangulating in this way mitigates against “poorly shaped” triangles, meaning that it inherently avoids thin, elongated triangles with ill-defined behavior. Dividing the convex hull into the optimal or best configuration of triangles includes determining a set of triangulations of nearly equilateral triangles of nearly equal size. This may be performed by returning the triangulation which has the largest minimum angle among all constituent triangles.

Interpolation includes interpolating all points that belong to a known triangle T by applying bivariate linear interpolation (e.g., within the convex hull 1011), which is done by defining a linear system of three equations which references the (x,y) coordinates and the bias value for each of the three vertices defining triangle T. The plot 1015 of FIG. 10D shows an example of a triangle T denoted by points {A, B, C}. When interpolating, the algorithm will assign interpolant point {P} to a constituent triangle, and use the values associated with points {A, B, C} to determine its interpolated value. Once the input dataset is triangulated as shown in the plot 1015 of FIG. 10D, bivariate linear interpolation is performed for points within the convex hull 1011 (e.g., defining the interpolation-extrapolation boundary). Interpolation is linear within the convex hull 1011. For data points outside the convex hull 1011, values are determined using boundary extrapolation. The boundary extrapolation maintains continuity by extending the values on the interpolation boundary into the extrapolation domain. The plot 1020 of FIG. 10E illustrates the results of such linear interpolation and boundary extrapolation. It should be noted that use of linear interpolation within the convex hull 1011 is just an example. In the absence of a low-pass filter to act as a smoothing function, linear interpolation provides good results. In other examples, cubic interpolation may be used. Cubic interpolation may provide better results than linear interpolation when data smoothing is applied (e.g., utilizing a smoothing function such as a low-pass filter) and the input data is denser. Cubic interpolation, however, requires more information around the triangle edges to yield a better estimate of the gradient on either side.

After executing the scattered data interpolation, the interpolated data may be post-processed before being exported to the OPC engine. First, the data may be smoothed using a moving average technique. This is done to mitigate against outlier CD-SEM data that may be present in the sparse input dataset. Outlier input data introduces significant noise into the interpolation routine, resulting in errant interpolation values for all neighboring points. Where MATLAB is used, the smoothdata function may be used. The smoothdata function operates along each column of the interpolated output data. Next, the output data is rounded (e.g., to the nearest 0.5 nm). This is done because the OPC grid size for the input level of interest is 0.5 nm, meaning that all mask geometry distortions are limited to a resolution of 0.5 nm. Next, the diff function of MATLAB is used to calculate the finite difference of the rounded interpolation matrix along each data column. This is done as an efficiency enhancement in order to limit binning table definitions to geometries which are prescribed a different bias treatment from the previous bin. If this processing is skipped, the output table would contain thousands of redundant bins, significantly increasing the runtime of the algorithm. The matrix indices for nonzero finite differences are then extracted and exported (e.g., in a .csv format) similar to the input dataset. This output file is then parsed in a Python routine to generate the final RBT which is called by the RB-OPC model. The Python framework may be used to reference the RBT as a .py file. Each rule definition within the RBT includes a minimum and maximum feature width, a minimum and maximum space width, and the bias per edge to be applied.

After the RBT is finalized and exported, MB-OPC using the optical OPC model is executed on a copy of the OPC validation module for this implant level. The OPC validation module is a collection of 1D and 2D features at various drawn sizes through pitch. After MB-OPC is completed, the OPC model is then corrected using RB-OPC with the exported RBT (e.g., produced using scattered data interpolation). Once the rules-based optical OPC model correction is applied, the features within the OPC module may be analyzed using an exclusive-or (XOR) analysis.

The accuracy of the OPC model may be characterized using metrics such as the RMSE and the range of residual values. Table 2 below shows head-to-head performance of the empirical OPC model versus the optical OPC model without RB-OPC using RMSE and residual value range metrics:

TABLE 2
Comparison of Empirical and Optical
OPC Model Performance (units in nm)

| | Empirical | Optical |
|---|---|---|
| 1D RMSE | 2.492 | 3.33 |
| 1D Range | 14.45 | 20.05 |
| 2D RMSE | 9.681 | 26.16 |
| 2D Range | 15.46 | 61.59 |

As expected, the empirical OPC model is more accurate than the optical OPC model when no post-model correction is applied. This occurs because the empirical OPC model parameters were tuned specifically to fit the empirical calibration dataset, while the optical OPC model was only configured to target the process anchor. As shown in Table 2, there is a difference in performance for 1D and 2D features, where the 2D feature performance is degraded significantly relative to the 1D features. This is likely because resist contributions such as acid/base diffusion and pattern loading become much more predominant in 2D features, while they can be reasonably neglected in the 1D case.

To validate the performance of the scattered data interpolation technique, in lieu of empirical measurement data, mask XORs are run on copies of the OPC validation module with the following OPC treatments applied: (1) baseline OPC treatment with the empirically calibrated OPC model; (2) OPC treatment with the optical OPC model only; and (3) OPC treatment with the optical OPC model and post-model correction with RB-OPC (e.g., using an RBT with data interpolated utilizing scattered data interpolation). Mask XORs are leveraged to confirm that the algorithm functions as expected by applying appropriate mask bias corrections.

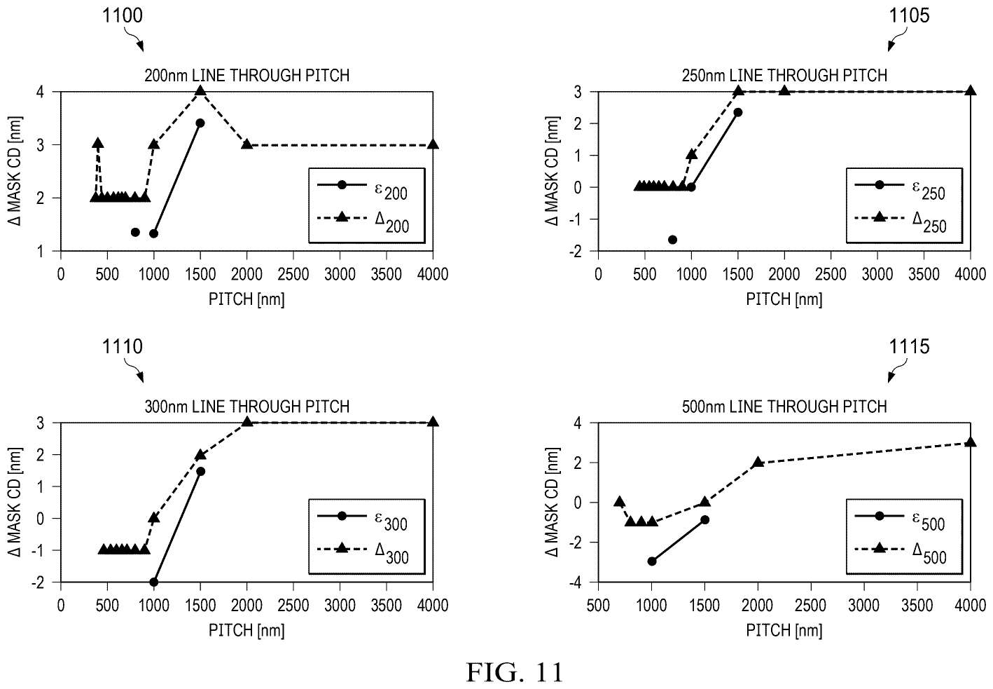

Referring now to FIG. 11, plots 1100, 1105, 1110 and 1115 are shown highlighting the performance of the RB-OPC solution with interpolated data for 1D LTP features for 200 nm LTP, 250 nm LTP, 300 nm LTP and 500 nm LTP, respectively. This is assessed by finding features that are an exact match in terms of feature size and pitch between the model verification dataset and the OPC validation module. Because the MEEF is assumed to be 1, there should be a 1:1 correspondence between the calculated model error and the subsequent RB-OPC treatment for equivalent features. The quantified model residuals are depicted in each of the plots 1100, 1105, 1110 and 1115 as e, and the RB-OPC mask treatments are depicted A. In the case of equivalent features, all treatments fall within 2 nm of the quantified model error, demonstrating that this algorithm functions as expected for 1D line features. The XOR analysis on the LTP structures shows good agreement between the quantified optical model error (e) and the RB-OPC treatment applied to compensate for such error (A). This assessment holds true for the 200 nm features shown in plot 1100, the 250 nm features shown in plot 1105, the 300 nm features shown in plot 1110, and the 500 nm features shown in plot 1115.

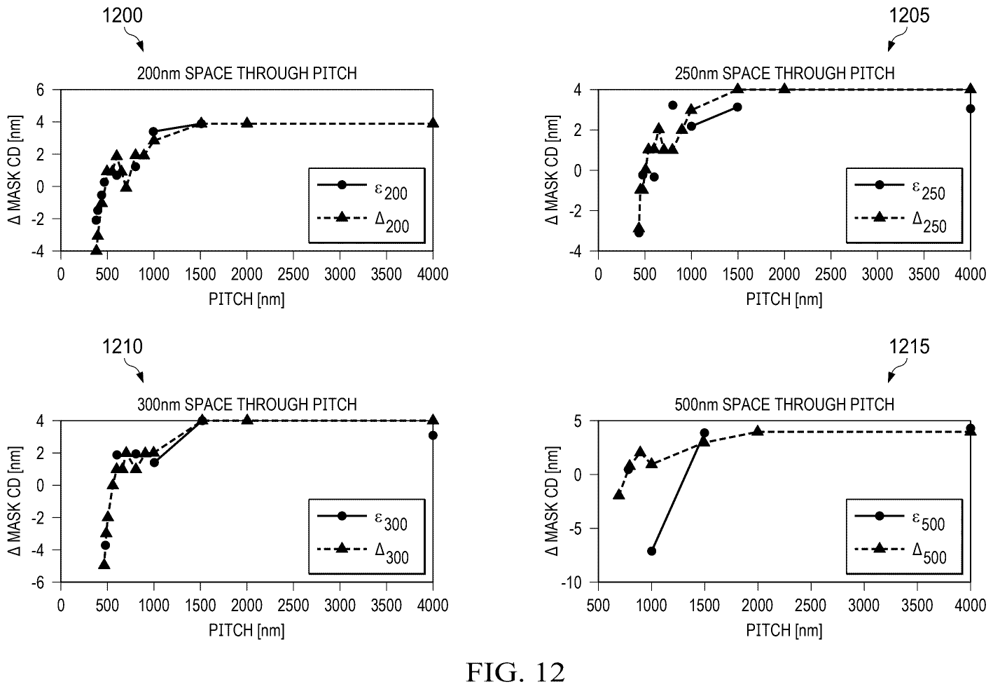

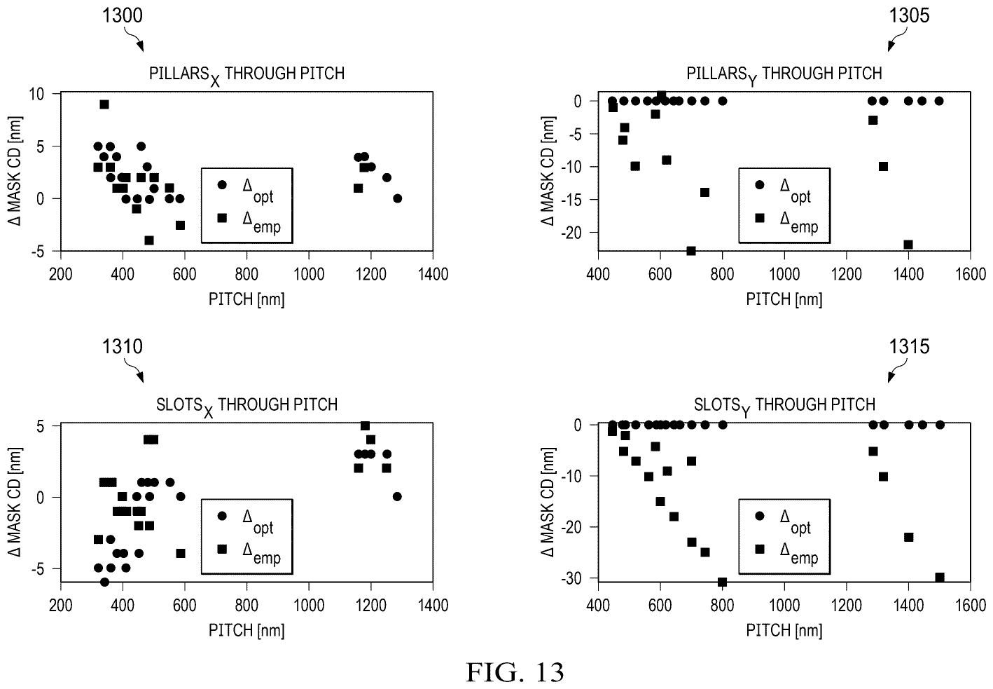

Referring now to FIG. 12, plots 1200, 1205, 1210 and 1215 are shown highlighting the performance of the RB-OPC solution with interpolated data for 1D STP features for 200 nm STP, 250 nm STP, 300 nm STP and 500 nm STP, respectively. Again, the results are assessed using the quantified model error (e) and the RB-OPC treatment applied to compensate for such error (Δ). All features except one fall within a 2 nm range of the expected correction. The one exception, for the 500 nm space feature on 1000 nm pitch, is attributed to poor metrology for this feature. This particular feature was duplicated within both the LTP and STP calibration data, meaning that both the L500/P1000 and S500/P1000 features were measured and included. The sum of the resist CD values for both features summed to 1010 nm, meaning that there is approximately 10 nm of metrology offset that was not properly assessed in the model verification stage. Taking this outlier into consideration, the RB-OPC performance for STP features still exceeds expectations.

Referring now to FIG. 13, plots 1300, 1305, 1310 and 1315 are shown highlighting the performance of the RB-OPC solution with interpolated data for 2D features. Plots 1300 and 1305 show results for pillar features, while plots 1310 and 1315 show results for slot features. The plots 1300, 1305, 1310 and 1315 illustrate two methods of comparison: Δₑₘₚ representing the difference between the optical model with RB-OPC treatment and a baseline empirical model, illustrated using circular data points; and Δₒₚₜ representing the different between the optical model treatment with and without RB-OPC treatment post MB-OPC, illustrated using square data points. The clustering of the circular and square data points for the 2D features in the x-orientation (e.g., plots 1300 and 1310 for both pillars and slots) indicate reasonable agreement between the empirical OPC model and the optical OPC model with RB-OPC correction using interpolated data. The results for the y-dimension uncovered two issues. The large negative Δₑₘₚ values between the optical and empirical OPC treatments (e.g., square data points) indicate that the optical OPC model dramatically over-predicted the contour CD values for these features for both pillars and slots as shown in the plots 1305 and 1315. As a consequence, the ensuing OPC treatment dramatically undersized 2D features along the y-axis. The zero Δₒₚₜ values between the non-RB-OPC treated and RB-OPC treated features (e.g., circular data points) indicate that the RB-OPC routine did not execute along the y-axis; that is, the mask CD values did not change before and after receiving corrective RB-OPC.

In some examples, a scattered data interpolation framework is developed for applications in automating generation of data for RBTs for RB-OPC. In some examples, the scattered data interpolation utilizes Delaunay triangulation to convert a sparse input dataset (e.g., a RBT such as the table 1000 shown in FIG. 10A) into a fully interpolated 2D surface (e.g., the plot 1020 shown in FIG. 10E) to correct quantified optical OPC model error (e.g., for a 28 nm implant process). Once the interpolated surface is generated, it can be passed into an RB-OPC engine and used to generate an OPC validation module. In some cases, separate RBTs (separate rules-based OPC data structures) may be defined independently for 1D and 2D features, as the optical behavior differs between 1D and 2D features of equivalent size.

Defining binning corrections for RB-OPC requires extensive empirically measured CD-SEM or TEM input data. Because empirical data collections is resource- and time-intensive, the final data provided to OPC engineers for correction is often sparse and incomplete, as illustrated in the table 1000 shown in FIG. 10A. In some examples, an automated multivariate interpolation solution is utilized to programmatically populate RBTs and eliminate or reduce manual interpolation, which is error-prone and resource-intensive. This solution can be used for applications in OPC model correction and other OPC applications such as etch bias and silicon process bias handling. Conventional approaches for handling RBTs with sparse empirical data include use of a “stairstep” approach or manual interpolation. In the stairstep approach, empty cell entries are eliminated and only the sparse input is used to define the RBT. Manual interpolation includes interpolation by hand, using engineering judgment to fill in gaps. Manual interpolation for 1D features is time-consuming, resource-intensive and error prone. Manual interpolation for 2D features is difficult to conceptualize and practically impossible for higher-dimensional arrays.

In some examples, a method for automating binning table definitions in RB-OPC is utilized. Rather than manually interpolating binning tables for RB-OPC applications, an automated interpolation solution is used which performs scattered data interpolation based on the Delaunay triangulation method. An OPC processing flow in conventional approaches necessitates that an OPC engineer works in conjunction with a lithography engineer to generate empirically-driven rules to correct known errors, such as OPC model error, etch bias, etc. Since the empirical data is sparsely populated, the OPC engineer currently interpolates between data points manually. This is time-consuming and risky (e.g., error-prone), since it relies on engineering judgment. In some examples, empirically defined binning rules are processed (e.g., in CSV format), where the input binning table can be readily converted into a Numpy array using Python routines. Binning rules for previously undefined bins are then defined using scattered data interpolation. The scattered data interpolation may use Delaunay triangulation to interpolate the appropriate value, which triangulates the three nearest-neighboring data points and interpolates between them.

Once robust binning rules are output at a user-defined granularity and precision, a post-processing step converts the full binning table into a format (e.g., a CSV format) suitable for input into OPC software. In some examples, a smoothing function is used when generating the output binning rules (e.g., an output RBT with interpolated data). Further, the output may truncate all data to a nearest DBU. The output table construction allows for sampling at an arbitrary frequency based on the application need. For example, metal etch bias may require higher-resolution sampling because etch response can be very non-linear. Implant OPC model correction, in some examples, may be adequately parameterized by coarser sampling because behavior is essentially linear. In some examples, a finite difference of the output array is calculated, only returning points at which the bias value changes. This advantageously reduces redundant points that lead to increased runtime for OPC. The approaches described herein for RB-OPC with RBTs constructed using scattered data interpolation are advantageously able to accelerate OPC development cycle time while mitigating errors associated with manual interpolation (e.g., typographical errors in manual data entry, incorrect engineering assumptions, etc.).

Generating a photomask corrected using OPC may begin with empirical data collection (e.g., by wafer fabrication), followed by defining a sparse RBT (e.g., sparse binning table definition). Next, interpolation is performed to define intermediate binning rules (e.g., those not defined in the sparse RBT). This may include automating RB-OPC via scattered data interpolation, including: data preprocessing where input data (e.g., in CSV format) is converted into an array (e.g., a Numpy array); output array definition, which defaults to boundary conditions of the input data table; executing an automated interpolation routine, such as scattered data interpolation using Delaunay triangulation; and data postprocessing converting the output (e.g., a Numpy array) into a format (e.g., CSV format) suitable for input to OPC software. This output binning table is integrated into the OPC “recipe” and used to generate a photomask corrected by the OPC recipe.

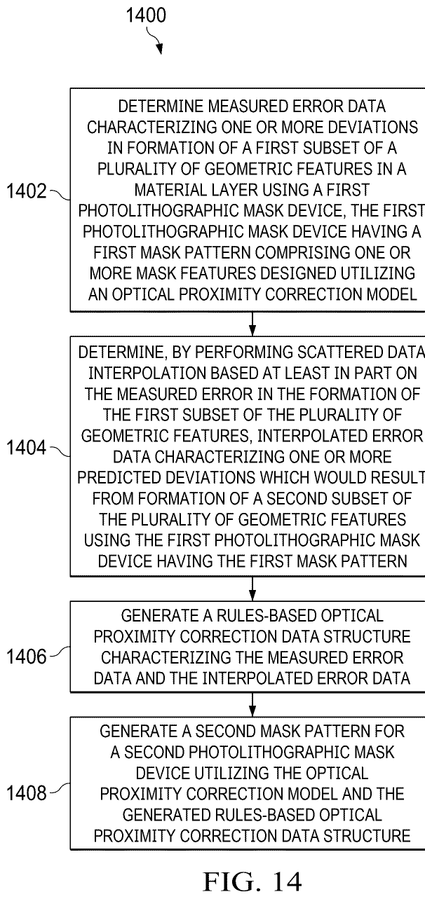

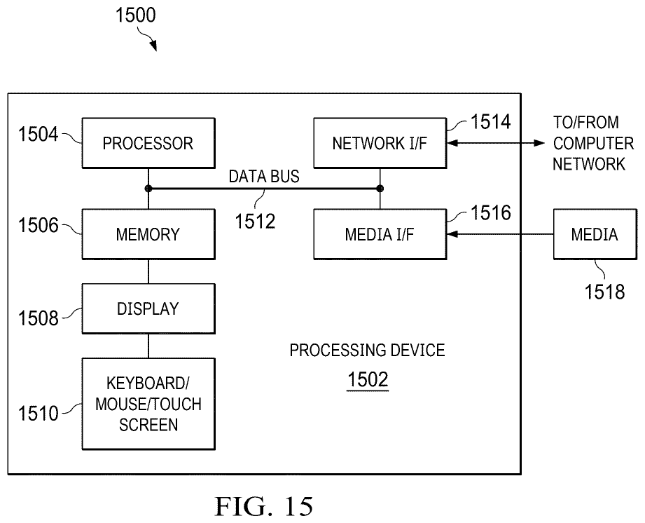

Referring now to FIG. 14, a process flow 1400 for photolithographic mask pattern generation with RB-OPC using OPC rules determined using scattered data interpolation will be described. In block 1402, measured error data characterizing one or more deviations in formation of a first subset of a plurality of geometric features in a material layer using a first photolithographic mask device is determined. The first photolithographic mask device having a first mask pattern comprising one or more mask features designed utilizing an OPC model.

In block 1404, interpolated error data characterizing one or more predicted deviations which would result from formation of a second subset of the plurality of geometric features using the first photolithographic mask device having the first mask pattern is determined by performing scattered data interpolation based at least in part on the measured error in the formation of the first subset of the plurality of geometric features. Performing the scattered data interpolation may utilize Delaunay triangulation. In some examples, performing the scattered data interpolation comprises: determining an interpolation-extrapolation boundary of the measured error data; applying interpolation to determine a first portion of the interpolated error data within the interpolation-extrapolation boundary; and applying extrapolation to determine a second portion of the interpolated error data outside the interpolation-extrapolation boundary. Determining the interpolation-extrapolation boundary of the measured error data may include computing a convex hull of the measured error data plotted in a two-dimensional space. Applying the interpolation to determine the first portion of the interpolated error data within the interpolation-extrapolation boundary may include: determining a set of triangles within the interpolation-extrapolation boundary, each triangle being associated with a set of three data points in the measured error data; and performing interpolation of data points within the interpolation-extrapolation boundary utilizing, for each triangle in the set of triangles, the measured error data for the set of three data points associated with each triangle. The interpolation of the data points within the interpolation-extrapolation boundary may be a bivariate linear interpolation or a cubic interpolation. Applying the extrapolation to determine the second portion of the interpolated error data may include performing boundary extrapolation utilizing values of data points along the interpolation-extrapolation boundary.

In block 1406, a rules-based OPC data structure is generated characterizing the measured error data and the interpolated error data. The rules-based OPC data structure may comprise one or more RBTs specifying feature-specific modifications for ones of the plurality of geometric features. The feature-specific modification for a given one of the plurality of geometric features may specify a mask bias adjustment computed based at least in part on a MEEF computed for the given one of the plurality of geometric features.

In block 1408, a second mask pattern for a second photolithographic mask device is generated utilizing the OPC model and the generated rules-based OPC data structure. The second mask pattern may be applied, utilizing a pattern applying tool, to generate the second photolithographic mask device. In some examples, a method of fabricating a semiconductor device includes forming, utilizing the second photolithographic mask device having the second mask pattern, the one or more geometric features in a material layer.

Referring now to FIG. 15, a computer system 1500 in accordance with which one or more examples can be implemented is illustrated. That is, one, more than one, or all of the components and/or functionalities shown and described in the context of FIGS. 1-14 can be implemented via the computer system 1500 depicted in FIG. 15. FIG. 15 shows a processing device 1502 including a processor 1504, a memory 1506, and an input/output (I/O) interface formed by a display 1508 and a keyboard/mouse/touchscreen 1510, sometimes referred to generally as “devices”. More or fewer devices may be part of the I/O interface. The processor 1504, memory 1506 and I/O interface are interconnected via data bus 1512 as part of the processing device 1502 (e.g., a computer, workstation, server, client device, etc.). Interconnections via data bus 1512 are also provided to a network interface 1514 and a media interface 1516. Network interface 1514 (which can include, for example, transceivers, modems, routers and Ethernet cards) enables the system to couple to other processing systems or devices (such as remote displays or other computing and storage devices) through intervening private or public computer networks (wired and/or wireless). Media interface 1516 (which can include, for example, a removable disk drive) interfaces with media 1518.

The processor 1504 can include, for example, a central processing unit (CPU), a microprocessor, a microcontroller, an application-specific integrated circuit (ASIC), a field programmable gate array (FPGA) or other type of processing circuitry, as well as portions or combinations of such circuitry elements. Components of systems as disclosed herein can be implemented at least in part in the form of one or more software programs stored in memory and executed by a processor of a processing device such as processing device 1502. Memory 1506 (or another storage device) having such program code embodied therein is an example of what is more generally referred to herein as a processor-readable storage medium. Articles of manufacture may comprise such processor-readable storage media. A given such article of manufacture may comprise, for example, a storage device such as a storage disk, a storage array or an integrated circuit containing memory. The term “article of manufacture” as used herein should be understood to exclude transitory, propagating signals.

Furthermore, memory 1506 may comprise electronic memory such as random-access memory (RAM), read-only memory (ROM) or other types of memory, in any combination. The one or more software programs when executed by the processing device 1502 causes the device to perform functions associated with one or more of the components/steps of system/methodologies in FIGS. 1-14. One skilled in the art would be readily able to implement such software given the teachings provided herein. Other examples of processor-readable storage media may include, for example, optical or magnetic disks.

Still further, the I/O interface formed by devices 1508 and 1510 is used for inputting data to the processor 1504 and for providing initial, intermediate and/or final results associated with the processor 1504.

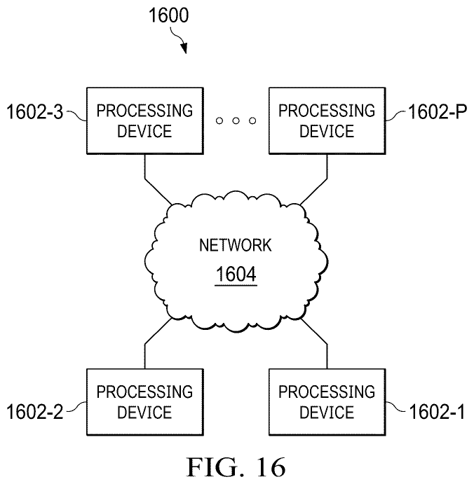

Referring now to FIG. 16, a processing platform 1600 in accordance with which one or more examples can be implemented is shown. FIG. 16 shows a distributed communications/computing network that includes a plurality of computing or processing devices 1602-1 through 1602-P (herein collectively referred to as computing or processing devices 1602) configured to communicate with one another over a network 1604.

It is to be appreciated that one, more than one, or all of the computing devices 1602 in FIG. 16 may be configured in a manner similar to that of the processing device 1502 of FIG. 15. It is to be appreciated that the methodologies described herein may be executed in one such computing device 1602, or executed in a distributed manner across two or more of such computing devices 1602. It is to be further appreciated that a server, a client device, a processing device or any other processing platform element may be viewed as an example of what is more generally referred to herein as a “computing device.” The network 1604 may include, for example, a global computer network such as the Internet, a wide area network (WAN), a local area network (LAN), a satellite network, a telephone or cable network, or various portions or combinations of these and other types of networks (including wired and/or wireless networks).

As described herein, the computing devices 1602 may represent a large variety of devices. For example, the computing devices 1602 can include a portable device such as a mobile telephone, a smart phone, personal digital assistant (PDA), tablet, computer, a client device, etc. The computing devices 1602 may alternatively include a desktop or laptop personal computer, a server, a microcomputer, a workstation, a kiosk, a mainframe computer, or any other information processing device which can implement any or all of the techniques detailed in accordance with one or more examples.

One or more of the computing devices 1602 may also be considered a “user.” The term “user,” as used in this context, should be understood to encompass, by way of example and without limitation, a user device, a person utilizing or otherwise associated with the device, or a combination of both. An operation described herein as being performed by a user may therefore, for example, be performed by a user device, a person utilizing or otherwise associated with the device, or by a combination of both the person and the device, the context of which is apparent from the description.

Additionally, as noted herein, one or more modules, elements or components described in connection with examples can be located geographically-remote from one or more other modules, elements or components. That is, for example, the modules, elements or components shown and described in the context of FIGS. 1-14 can be distributed in an Internet-based environment, a mobile telephony-based environment, a kiosk-based environment and/or a local area network environment. The systems described herein are not limited to any particular one of these implementation environments. However, depending on the operations being performed by the system, one implementation environment may have some functional and/or physical benefits over another implementation environment.

The processing platform 1600 shown in FIG. 16 may comprise additional known components such as batch processing systems, parallel processing systems, physical machines, virtual machines, virtual switches, storage volumes, etc. Again, the particular processing platform shown in this figure is presented by way of example only, and may include additional or alternative processing platforms, as well as numerous distinct processing platforms in any combination. Also, numerous other arrangements of servers, clients, computers, storage devices or other components are possible in processing platform 1600.

Furthermore, it is to be appreciated that the processing platform 1600 of FIG. 16 can comprise virtual machines (VMs) implemented using a hypervisor. A hypervisor is an example of what is more generally referred to herein as “virtualization infrastructure.” The hypervisor runs on physical infrastructure. As such, the techniques illustratively described herein can be provided in accordance with one or more cloud services. The cloud services thus run on respective ones of the virtual machines under the control of the hypervisor. Processing platform 1600 may also include multiple hypervisors, each running on its own physical infrastructure. Portions of that physical infrastructure might be virtualized.

As is known, virtual machines are logical processing elements that may be instantiated on one or more physical processing elements (e.g., servers, computers, processing devices). That is, a “virtual machine” generally refers to a software implementation of a machine (i.e., a computer) that executes programs like a physical machine. Thus, different virtual machines can run different operating systems and multiple applications on the same physical computer. Virtualization is implemented by the hypervisor which is directly inserted on top of the computer hardware in order to allocate hardware resources of the physical computer dynamically and transparently. The hypervisor affords the ability for multiple operating systems to run concurrently on a single physical computer and share hardware resources with each other.

It is to be appreciated that combinations of the different implementation environments may be used in some examples. One of ordinary skill in the art will realize alternative implementations given the illustrative teachings provided herein.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method, comprising:
determining measured error data characterizing one or more deviations in formation of a first subset of a plurality of geometric features in a material layer using a first photolithographic mask device, the first photolithographic mask device having a first mask pattern comprising one or more mask features designed utilizing an optical proximity correction model;
determining, by performing scattered data interpolation based at least in part on the measured error in the formation of the first subset of the plurality of geometric features, interpolated error data characterizing one or more predicted deviations which would result from formation of a second subset of the plurality of geometric features using the first photolithographic mask device having the first mask pattern;
generating a rules-based optical proximity correction data structure characterizing the measured error data and the interpolated error data; and
generating a second mask pattern for a second photolithographic mask device utilizing the optical proximity correction model and the generated rules-based optical proximity correction data structure.

2. The method of claim 1, wherein the rules-based optical proximity correction data structure comprises one or more rules-based tables specifying feature-specific modifications for ones of the plurality of geometric features.

3. The method of claim 2, wherein the feature-specific modification for a given one of the plurality of geometric features specifies a mask bias adjustment computed based at least in part on a mask error enhancement factor computed for the given one of the plurality of geometric features.

4. The method of claim 1, wherein performing the scattered data interpolation utilizes Delaunay triangulation.

5. The method of claim 1, wherein performing the scattered data interpolation comprises:
determining an interpolation-extrapolation boundary of the measured error data;
applying interpolation to determine a first portion of the interpolated error data within the interpolation-extrapolation boundary; and
applying extrapolation to determine a second portion of the interpolated error data outside the interpolation-extrapolation boundary.

6. The method of claim 5, wherein determining the interpolation-extrapolation boundary of the measured error data comprises computing a convex hull of the measured error data plotted in a two-dimensional space.

7. The method of claim 5, wherein applying the interpolation to determine the first portion of the interpolated error data within the interpolation-extrapolation boundary comprises:
determining a set of triangles within the interpolation-extrapolation boundary, each triangle being associated with a set of three data points in the measured error data; and
performing interpolation of data points within the interpolation-extrapolation boundary utilizing, for each triangle in the set of triangles, the measured error data for the set of three data points associated with each triangle.

8. The method of claim 7, wherein the interpolation of the data points within the interpolation-extrapolation boundary comprises a bivariate linear interpolation.

9. The method of claim 7, wherein the interpolation of the data points within the interpolation-extrapolation boundary comprise a cubic interpolation.

10. The method of claim 5, wherein applying the extrapolation to determine the second portion of the interpolated error data comprises performing boundary extrapolation utilizing values of data points along the interpolation-extrapolation boundary.

11. The method of claim 1, further comprising applying the second mask pattern utilizing a pattern applying tool to generate the second photolithographic mask device.

12. An apparatus, comprising:
at least one processor; and
at least one memory storing instructions that, when executed by the at least one processor, cause the apparatus at least to:
determine measured error data characterizing one or more deviations in formation of a first subset of a plurality of geometric features in a material layer using a first photolithographic mask device, the first photolithographic mask device having a first mask pattern comprising one or more mask features designed utilizing an optical proximity correction model;
determine, by performing scattered data interpolation based at least in part on the measured error in the formation of the first subset of the plurality of geometric features, interpolated error data characterizing one or more predicted deviations which would result from formation of a second subset of the plurality of geometric features using the first photolithographic mask device having the first mask pattern;
generate a rules-based optical proximity correction data structure characterizing the measured error data and the interpolated error data; and
generate a second mask pattern for a second photolithographic mask device utilizing the optical proximity correction model and the generated rules-based optical proximity correction data structure.

13. The apparatus of claim 12, wherein the rules-based optical proximity correction data structure comprises one or more rules-based tables specifying feature-specific modifications for ones of the plurality of geometric features.

14. The apparatus of claim 13, wherein the feature-specific modification for a given one of the plurality of geometric features specifies a mask bias adjustment computed based at least in part on a mask error enhancement factor computed for the given one of the plurality of geometric features.

15. The apparatus of claim 12, wherein performing the scattered data interpolation utilizes Delaunay triangulation.

16. A method of fabricating a semiconductor device, comprising:
generating, utilizing an optical proximity correction model, a first mask pattern for formation of one or more geometric features using a first mask pattern comprising a first set of one or more mask features;
determining, based at least in part on a rules-based optical proximity correction data structure, one or more adjustments to the first mask pattern to generate a second mask pattern, wherein the rules-based optical proximity correction data structure characterizes one or more predicted deviations which would result from formation of at least one of the one or more geometric features utilizing the first mask pattern, the one or more predicted deviations being determined by performing scattered data interpolation on measured error data; and
forming, utilizing a photolithographic mask device having the second mask pattern, the one or more geometric features in a material layer over a semiconductor substrate.

17. The method of claim 16, wherein the rules-based optical proximity correction data structure comprises one or more rules-based tables specifying feature-specific modifications for ones of the one or more geometric features.

18. The method of claim 17, wherein the feature-specific modification for a given one of the one or more geometric features specifies a mask bias adjustment computed based at least in part on a mask error enhancement factor computed for the given one of the one or more geometric features.

19. The method of claim 16, wherein performing the scattered data interpolation utilizes Delaunay triangulation.

20. A semiconductor device comprising the material layer with the one or more geometric features formed utilizing the method of claim 16.
